(19) United States
(12) Patent Application Publication
(10) Pub. No.: US 2005/0225938 A1
(43) Pub. Date: Oct. 13, 2005

(54) Cold plate

(76) Inventors: Richard Montgomery, Puyallup, WA (US); William E. Berry, Lakewood, WA (US); Stephen W. Montgomery, Seattle, WA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/822,054

(22) Filed: Apr. 8, 2004

(51) Int. Cl. H05K 7/20

(52) U.S. Cl. 361/695

(57) ABSTRACT

A novel cold plate may include one or more of the following features: radial flow paths, and/or an impingement point for cooling fluid in the cold plate located at a position corresponding to an expected relatively hotter spot of a heat source.

The invention relates to thermal management of electronic systems, and more particularly to a novel cold plate for a liquid cooling system.

### BACKGROUND AND RELATED ART

Modern electronic devices such as computer systems have not only microprocessor chips, including Intel® i386, i486, Celeron™ or Pentium® processors, but also many other integrated circuits (ICs) and other electronic components, most of which are mounted on printed circuit boards (PCBs). Many of these components generate heat during normal operation. Components that have a relatively small number of functions in relation to their size, as for example individual transistors or small scale integrated circuits (ICs), usually dissipate all their heat without a heatsink. However, more complex components may dissipate an amount of heat which requires the assistance of external cooling devices such as heatsinks.

Heatsinks may be passive devices, for example an extruded aluminum plate with a plurality of fins, that are thermally coupled to a heat source, e.g. an electronic component such as a microprocessor, to absorb heat from the electronic component. The heatsinks dissipate this heat into the air primarily by convection.

Common materials for heatsinks include copper (Cu) or aluminum (Al) based heatsinks with either extruded, folded, or skived fins with no fan or with an active fan to promote airflow efficiency. A retention mechanism such as a clip is sometimes required to secure the heatsink onto an electronic package across the heat dissipation path. An active fan is often mounted on top of the heatsinks to transfer heat, during operation, from a heat source to the ambient air, via the fins.

High power electronic systems such as consumer computer systems or servers may require or benefit from liquid cooling in place of or in addition to other cooling devices. With reference to FIG. 1, a liquid cooled system 10 includes a heat source 11 (e.g. a processor or other electronic device). A cold plate 12 is mechanically and thermally coupled to the heat source 11. The cold plate 12 is in liquid communication with a heat dissipation device 13 (e.g. a condenser and/or radiator). Cooling liquid is circulated from the cold plate 12 to the device 13 and back again to provide a cooling cycle. For example, the cold plate 12 may be connected in a loop to the device 13 by tubing 14. A pump 15 may be provided in line with one branch of the tubing 14 to circulate the cooling liquid contained in the tubing 14 (e.g. in the direction of arrows L). One function of the cold plate 12 is to transfer a heat load from the heat source 11 to the liquid that is circulated through the cold plate 12. The system 10 may include an optional fan 16 to provide air flow for the heat dissipation device 13 and/or the cold plate 12.

### BRIEF DESCRIPTION OF THE DRAWINGS

Various features of the invention will be apparent from the following description of preferred embodiments as illustrated in the accompanying drawings, in which like reference numerals generally refer to the same parts throughout the drawings. The drawings are not necessarily to scale, the emphasis instead being placed upon illustrating the principles of the invention.

FIG. 1 is a schematic view of a system utilizing liquid cooling.

FIG. 2 is a perspective view of a cold plate according to some embodiments of the invention.

FIG. 3 is an exploded, perspective view of the cold plate from FIG. 2.

FIG. 4 is a top view of a base portion of the cold plate according to some embodiments of the invention.

FIG. 5 is a side view of a base portion of the cold plate according to some embodiments of the invention.

FIG. 6 is a top view of a lid portion of the cold plate according to some embodiments of the invention.

FIG. 7 is a cross sectional view of a lid portion of the cold plate according to some embodiments of the invention, e.g. taken along line 7-7 in FIG. 6.

FIG. 8 is a front view of another cold plate according to some embodiments of the invention.

FIG. 9 is a cross sectional view of the cold plate from FIG. 8, taken along line 9-9 in FIG. 8.

FIG. 10 is a top view of a base portion of another cold plate according to some embodiments of the invention.

FIG. 11 is a perspective view of another cold plate according to some embodiments of the invention.

FIG. 12 is a perspective view of another cold plate according to some embodiments of the invention.

### DESCRIPTION

In the following description, for purposes of explanation and not limitation, specific details are set forth such as particular structures, architectures, interfaces, techniques, etc. in order to provide a thorough understanding of the various aspects of the invention. However, it will be apparent to those skilled in the art having the benefit of the present disclosure that the various aspects of the invention may be practiced in other examples that depart from these specific details. In certain instances, descriptions of well known devices, circuits, and methods are omitted so as not to obscure the description of the present invention with unnecessary detail.

One aspect of some embodiments of the invention relates to providing radial flow paths in a cold plate. Another aspect of some embodiments of the invention relates to providing an impinging flow point near a relatively hotter spot of a heat source. According to some embodiments, a cold plate includes an enclosure having a fluid inlet and a fluid outlet in fluid communication with the fluid inlet, and a channel structure inside the enclosure between the inlet and the outlet defining a plurality of radial flow paths.

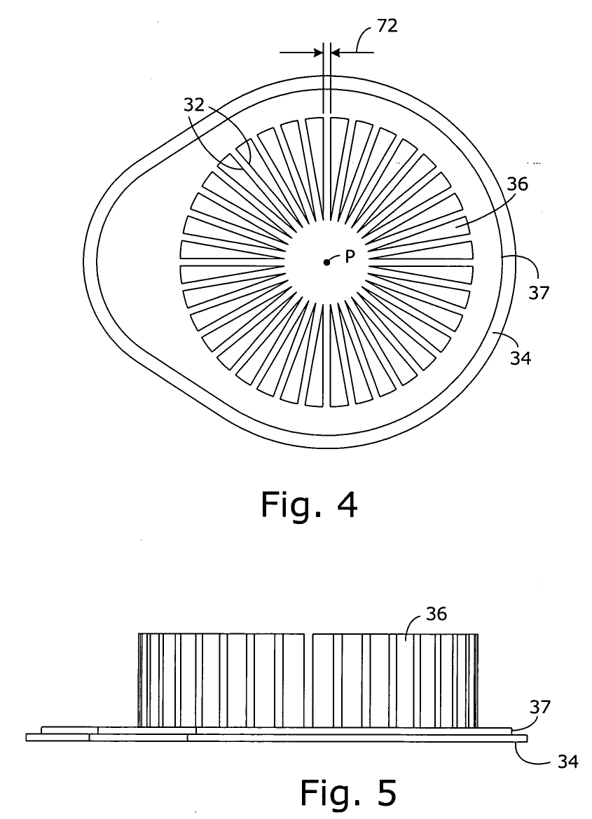

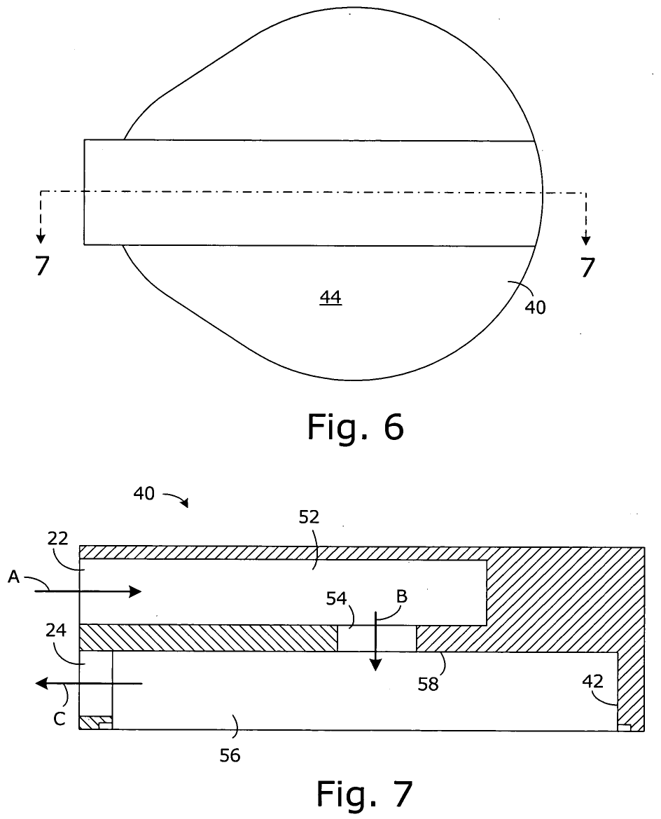

With reference to FIGS. 2-7, a cold plate 20 according to some embodiments of the invention is assembled from two sub-assemblies. The cold plate 20 includes a base member 30 with a set of cooling fins 36. The fins 36 provide a channel structure which define a plurality of radial flow paths originating at a fluid impingement point P and radiating outward to an outer perimeter of the cold plate 20. The fins have respective facing walls 32 which define respective channel gaps 72 (see FIG. 4). The radial paths are shown as substantially parallel, but this is not critical to any aspect of the invention.

The cold plate 20 further includes a lid member 40 defining an outermost channel wall 42, the lid member 40 being coupled to the base member 30 such that the assembly is sealed. A fluid inlet 22 is provided on either one of the base and lid members 30 and 40 (as illustrated the inlet 22 is provided on the lid member 40). A fluid outlet 24 is also provided on either one of the base and lid members 30 and 40 (as illustrated the outlet 24 is co-located with the inlet 22 on the lid member 40).

The channel walls 32 define radial flow paths from a nominal fluid impingement point P. For example, in some embodiments of the invention, the fluid impingement point P may be centrally located with respect to the fins 36. Preferably, the fluid impingement point P is located such that when the cold plate 20 is coupled to the heat source, the point P is near a relatively hotter spot of the heat source.

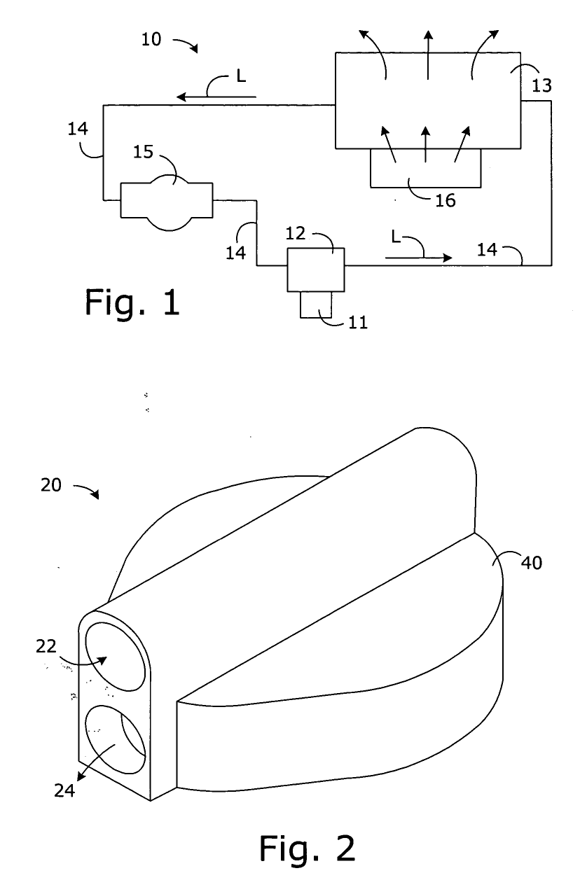

For example, some embodiments of the cold plate 20 (and other novel cold plates described herein) could be used in a system for cooling an electronic component, with the cold plate thermally coupled to the electronic component. In some applications, the system may be otherwise configured similarly as described above in connection with FIG. 1, with a heat dissipation device coupled to the cold plate 20 by a loop of tubing, cooling fluid disposed in the tubing, and a pump adapted to circulate the cooling fluid. An optional fan may be included to provide cooling air to at least one of the heat dissipation device and the cold plate 20. Typical applications for the cold plate 20 include cooling of processors or other electronic components in servers, desktop servers, and other computers.

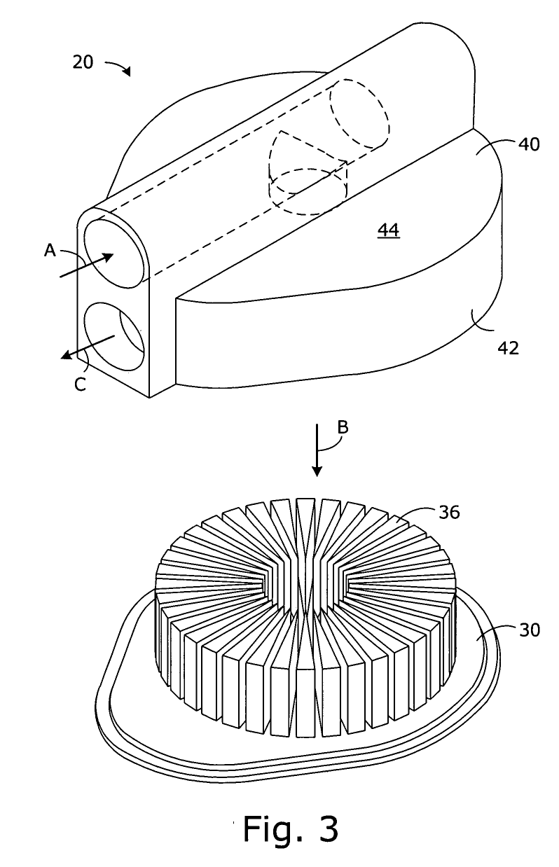

With reference to FIGS. 3-5, the base member 30 may be one half of a two piece assembly for the cold plate 20. The base member 30 may include a substantially planar base portion 34 with a plurality of substantially perpendicular protrusion or fins 36 extending from the base portion 34. For example, the fins 36 are arranged to form the set of channel walls 32. The base member 30 may include a shoulder 37 in the base portion 34. The shoulder 37 may be sized to fit tightly with the outermost wall 42 of the lid member 40.

The length or depth of the fins 36 of the first member 30 are preferably selected to contact an inside surface 58 of the lid member 40 (see FIG. 7). Preferably, leakage is inhibited between respective channel walls so that the fluid flows along desired paths. However, some leakage may be tolerated without substantially affecting the predominant flow paths. Although less preferred, in some embodiments the respective fins 36 may have selected lengths that do not contact both inside surfaces of the base and lid portions, such that flow paths are provided that flow over the walls 32 instead of or in addition to the channels between the walls.

With reference to FIGS. 3 and 6-7, the lid member 40 may be the other half of the two piece assembly for the cold plate 20. The lid member 40 may include a substantially planar portion 44 with the outermost wall 42 extending substantially perpendicular from the planar portion 44. For example, the outermost wall 42 is sealed to the base member 30 to provide a sealed assembly. For example, cooling fluid may enter the cold plate 20 at the inlet 22 along the direction of arrow A. The fluid flows along a passage 52 and through an opening 54 into a main chamber 56 of the cold plate 20. The fluid impinges on the base member 30 along the direction of arrow B at the impingement point P and then flows radially outward through the fins 36. The fluid then exits the cold plate 20 at the outlet 24 along the direction of arrow C.

An aspect of some embodiments of the invention relates to a preferred location for the inlet of the cold plate. In some embodiments, the inlet is located near a relatively hotter spot of the electronic component coupled to the cold plate. For example, in many electronic systems the component coupled to the cold plate is hottest near a central region of the cold plate. In accordance with some embodiments, cooling fluid enters an opening located in a central region of the cold plate. The fluid which circulates through the liquid cooling system may be about its coolest just before entering the cold plate. Advantageously, configuring the cold plate such that the cooler fluid enters the cold plate near a relatively hotter location on the electronic component increases the surface-to-fluid temperature difference across the cold plate and allows heat to be more efficiently transferred to the fluid (i.e. lower thermal resistance).

When the two members are sealed together, the resulting sealed enclosure may provide a high fluid channel aspect ratio. Copper or similar thermally performing materials may be preferred for a high performance cold plate. Alternatively, because some embodiments of the invention provide narrow channel gaps (which offer better thermal performance), lower performance materials such as aluminum may be utilized (at lower manufacturing costs) while providing satisfactory thermal performance.

The cold plate may be made by providing an enclosure having a fluid inlet and a fluid outlet in fluid communication with the fluid inlet, and forming a channel structure inside the enclosure between the inlet and the outlet defining a plurality of radial flow paths. For example, forming the channel structure may include disposing a plurality of cooling fins disposed between a lid member and a base member, the fins defining a set of channel walls which form radial flow paths from an impingement point radially outward to a perimeter of the enclosure. In some examples, the manufacturing process includes locating an impingement point for cooling fluid in the enclosure at a position corresponding to an expected relatively hotter spot of a heat source (e.g. locating the impingement point centrally with respect to the fins or offsetting the impingement point from a central region of the fins).

The two members may be manufactured by any previously known or hereinafter discovered technique for forming parts. For example, the two members 30 and 40 may be manufactured by machining, metal die-casting, powder metal/sintering, and forging. Preferably, each of the two members is manufactured as a monolithic sub-assembly. However, the two members 30 and 40 may be manufactured in several stages including, for example, forming the base and lid portions separately and thereafter attaching the protruding fins and/or walls. In addition, various of the features are only nominally associated with the lid and/or base. For example, in some embodiments the outermost wall 42 of the cold plate may be provided on the base member and one or more of the fins 36 may be provided on the lid member. It is believed that most of the cooling occurs at the walls, such that portions of the lid and/or base may be made from less thermally conductive materials (e.g. plastic, metal-clad plastic or ceramic).

The two members may be joined by any previously known or hereinafter discovered technique including sealing the two pieces around the perimeter, mechanical fitting (e.g. press fit), epoxy, metallurgical bond, and/or brazing. For example, the two halves of the cold plate 20 may be bonded together by either a brazing or soldering process around the circumference of the parts (e.g. at the junction of the shoulder 37 and the wall 42). The two members 30 and 40 may be further bonded at all of the interfacing protrusion features (e.g. between the fins 36 and the inside lid portion 58). Preferably, the bonding process seals the two members 30 and 40 together so that the cold plate 20 is a liquid tight unit. In addition, the bonding process preferably provides good thermal contact between the two members 30 and 40 for good thermal performance. A metallurgic bond may be preferred. However, the cold plate may be sealed with adhesives, mechanical fasteners, or other suitable techniques.

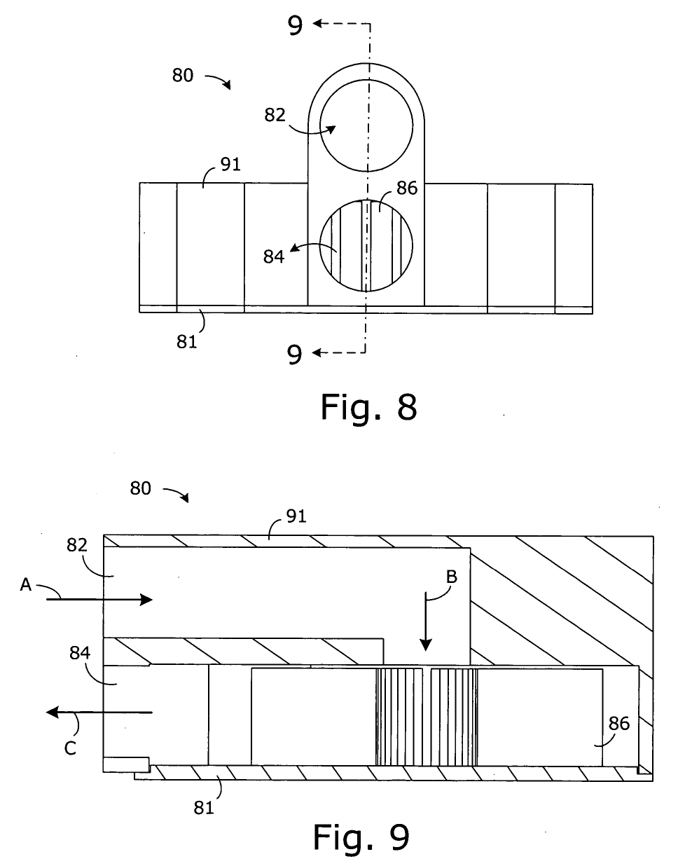

With reference to FIGS. 8-9, another cold plate 80 is similarly configured as described above with respect to the cold plate 20, with FIG. 9 showing a cross sectional view of the assembled cold plate 80. The cold plate 80 is assembled from a base portion 81 and a lid portion 91, which are joined together with a liquid tight seal. The base portion 81 includes a plurality of protruding fins 86 which define radial flow paths therebetween. The lid portion 91 includes an inlet 82 co-located with an outlet 84, with the general flow path following the direction of the arrows A, B, and C.

As shown in FIGS. 8-9, the fins 86 do not contact the inside surface of the lid portion 91. However, some alternative embodiments of the cold plate 80 may include some or all of the fins 86 extending further to contact the inside surface of the lid portion 91.

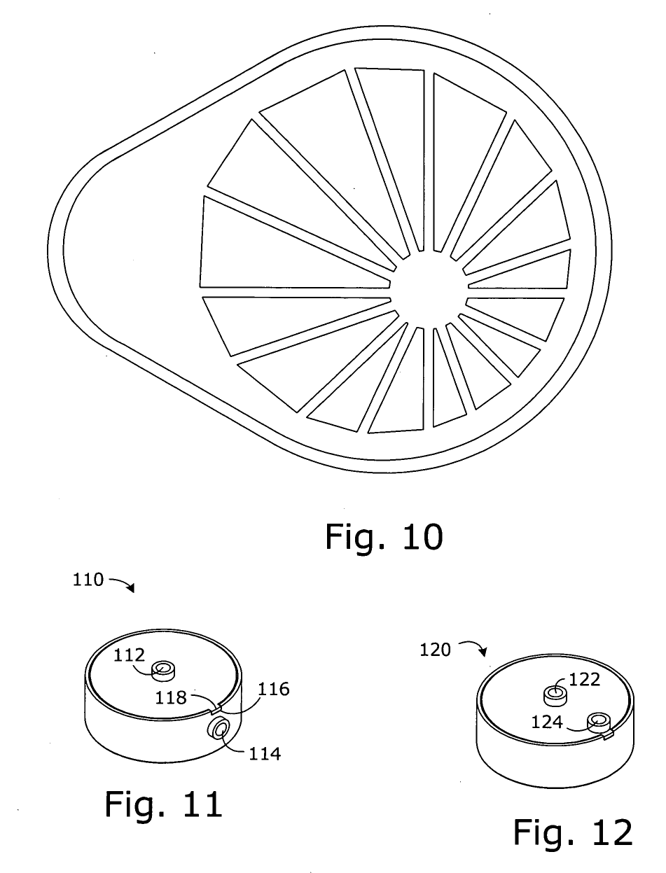

With reference to FIG. 10, another aspect of some embodiments of the invention relates to a preferred location for the impingement point of the cold plate. In some embodiments, the impingement point is located near a relatively hotter spot of the electronic component coupled to the cold plate. In FIG. 10, the channel structure defines a plurality of radial flow paths, with the impingement point offset from the central region of the fins. For example, the impingement point is positioned near a relatively hotter spot of a heat source. Advantageously, configuring the inlet such that the cooler fluid initially impinges near a relatively hotter location on the electronic component increases the surface-to-fluid temperature difference across the cold plate and allows heat to be more efficiently transferred to the fluid (i.e. lower thermal resistance).

With reference to FIGS. 11 and 12, the inlet and outlet for the cold plate may be positioned at any suitable location. The channel structure (not shown) inside the enclosures for both FIGS. 11 and 12, defines a plurality of radial flow paths. In FIG. 11, a cylindrically shaped cold plate 110 includes an inlet 112 centrally located on a lid member of the cold plate, and an outlet port 114 located on an outermost wall of a base member of the cold plate. In FIG. 12, a cold plate 120 includes an inlet 122 and an outlet 124 which are both located on a lid member of the cold plate 120. Alternatively, in some applications the inlet and outlet may both be located on the base portion and in other applications the inlet may be located on the base portion and the outlet may be located on the lid portion. In some embodiments, the inlet and outlet may be co-located or located very near to each other, with suitable flow paths provided on or internal to the cold plate between the inlet and the outlet. The cold plate may have any suitable shape or footprint, including for example, cylindrical (as illustrated), elliptical, and square or rectangular box-shaped or arbitrarily-shaped as may be desired for a particular application.

In some examples, the base member may define a shape which is sized to receive the lid member in only one possible orientation (e.g. the tear drop shape of FIGS. 2-7). For other shapes of the cold plate, the two members may include an optional keying feature to assist in providing a desired alignment of the two members. For example, in FIGS. 11 and 12 the base member may further define a slot 116 which is adapted to mate with a corresponding tab 118 in the lid member, or vice versa. Other indexing or keying features may be utilized.

The foregoing and other aspects of the invention are achieved individually and in combination. The invention should not be construed as requiring two or more of the such aspects unless expressly required by a particular claim. Moreover, while the invention has been described in connection with what is presently considered to be the preferred examples, it is to be understood that the invention is not limited to the disclosed examples, but on the contrary, is intended to cover various modifications and equivalent arrangements included within the spirit and the scope of the invention.

1. An apparatus, comprising:
an enclosure having a fluid inlet and a fluid outlet in fluid communication with the fluid inlet; and
a channel structure inside the enclosure between the inlet and the outlet defining a plurality of radial flow paths.

2. The apparatus of claim 1, wherein the enclosure comprises a lid member and a base member, and wherein the channel structure comprises:
a plurality of cooling fins disposed between the lid member and the base member, the fins defining a set of channel walls which form radial flow paths from an impingement point radially outward to a perimeter of the enclosure.

3. The apparatus of claim 2, wherein the impingement point is centrally located with respect to the fins.

4. The apparatus of claim 2, wherein the impingement point is offset from a central region of the fins.

5. The apparatus of claim 2, wherein the impingement point is located at a position corresponding to an expected relatively hotter spot of a heat source.

6. The apparatus of claim 1, wherein an impingement point for cooling fluid in the enclosure is located at a position corresponding to an expected relatively hotter spot of a heat source.

7. A method, comprising:
providing an enclosure having a fluid inlet and a fluid outlet in fluid communication with the fluid inlet; and
forming a channel structure inside the enclosure between the inlet and the outlet defining a plurality of radial flow paths.

8. The method of claim 7, wherein forming the channel structure comprises:
disposing a plurality of cooling fins disposed between a lid member and a base member, the fins defining a set of channel walls which form radial flow paths from an impingement point radially outward to a perimeter of the enclosure.

9. The method of claim 8, further comprising:
locating the impingement point centrally with respect to the fins.

10. The method of claim 8, further comprising:
offsetting the impingement point from a central region of the fins.

11. The method of claim 8, further comprising:
locating the impingement point at a position corresponding to an expected relatively hotter spot of a heat source.

12. The method of claim 7, further comprising:
locating an impingement point for cooling fluid in the enclosure at a position corresponding to an expected relatively hotter spot of a heat source.

13. A system, comprising:
an electronic component; and
a cold plate thermally coupled to the electronic component, the cold plate comprising:
an enclosure having a fluid inlet and a fluid outlet in fluid communication with the fluid inlet; and
a channel structure inside the enclosure between the inlet and the outlet defining a plurality of radial flow paths.

14. The system of claim 13, wherein the enclosure comprises a lid member and a base member, and wherein the channel structure comprises:
a plurality of cooling fins disposed between the lid member and the base member, the fins defining a set of channel walls which form radial flow paths from an impingement point radially outward to a perimeter of the enclosure.

15. The system of claim 14, wherein the impingement point is centrally located with respect to the fins.

16. The system of claim 14, wherein the impingement point is offset from a central region of the fins.

17. The system of claim 14, wherein the impingement point is located at a position corresponding to a relatively hotter spot of the electronic component.

18. The system of claim 13, wherein an impingement point for cooling fluid in the enclosure is located at a position corresponding to a relatively hotter spot of the electrical component.

19. The system of claim 13, further comprising:
a heat dissipation device coupled to the cold plate by a loop of tubing;
cooling fluid disposed in the tubing; and
a pump adapted to circulate the cooling fluid.

20. The system of claim 19, further comprising:
a fan adapted to provide cooling air to at least one of the heat dissipation device and the cold plate.
